(19) United States
(12) Patent Application Publication
(10) Pub. No.: US 2007/0230112 A1
(43) Pub. Date: Oct. 4, 2007

(54) NETWORK APPARATUS

(75) Inventor: Gwo-Liang Chen, Taoyuan County (TW)

Correspondence Address: J C PATENTS, INC., 4 VENTURE, SUITE 250, IRVINE, CA, 92618, US

(73) Assignee: ACCTON TECHNOLOGY CORPORATION, Hsinchu (TW)

(21) Appl. No.: 11/468,593

(22) Filed: Aug. 30, 2006

(30) Foreign Application Priority Data
Apr. 3, 2006 (TW) 95205643

(51) Int. Cl. G06F 1/20; H05K 7/20; H05K 5/00

(52) U.S. Cl. 361/687

(57) ABSTRACT

A network apparatus including a main frame, a power module, and a fan module is provided. The main frame has a first side surface and a second side surface adjacent to each other. An external alarming output/input interface, a display light set, and a plurality of serial COM ports are disposed on the first side surface. Furthermore, the first side surface has a first opening and a second opening, wherein the second opening is adjacent to the joint between the first and second side surfaces. The second side surface has a third opening. The power module, removable from the main frame, is installed in and electrically connected to the main frame through the first opening. The fan module, removable from the main frame, is installed in and electrically connected to the main frame through the second opening, wherein the airflow direction of the fan module is toward the third opening.

### CROSS-REFERENCE TO RELATED APPLICATION

This application claims the priority benefit of Taiwan application serial no. 95205643, filed on Apr. 3, 2006. All disclosure of the Taiwan application is incorporated herein by reference.

### BACKGROUND OF THE INVENTION

1. Field of Invention

The present invention relates to a network apparatus. More particularly, the present invention relates to a network apparatus adopting a special component configuration mode.

2. Description of Related Art

A conventional network apparatus mainly includes a main frame, a power module, a fan module, and a plurality of expansion modules. The main frame has a front side surface and a back side surface opposite to each other. Further, the main frame is provided with an external alarming output/input interface, a display light set, and a plurality of serial COM ports, wherein the external alarming output/input interface, display light set, and serial COM ports are disposed on the front side surface. The back side surface has a plurality of openings. The power module, fan module, and expansion modules are disposed in the main frame through the openings in the back side surface and are electrically connected to the main frame.

As the power module and the expansion modules are disposed at the back side surface of the main frame through the openings, when using the conventional network apparatus, the user must reserve a large space at the back of the network apparatus for accommodating the electrical wires and wirings connected to the power module and the expansion modules besides reserving a sufficient space in the front of the network apparatus for accommodating the wirings connected to the external alarming output/input interface and the serial COM ports. Therefore, in the design of the conventional network apparatus, a large space must be attained to accommodate the wirings and power lines of the conventional network apparatus and the wirings and power lines connected to the conventional network apparatus. As such, a waste of space results in the architecture of the network apparatus.

Moreover, as the power module, fan module, and expansion modules are disposed at the back side surface of the main frame, when the power module, fan module, or expansion modules are examined or replaced, such a configuration mode usually causes repair difficulties for users.

### SUMMARY OF THE INVENTION

An objective of the present invention is to provide a network apparatus for reducing the space required for constructing the network apparatus.

Another objective of the present invention is to provide a network apparatus that is easy to repair.

The present invention provides a network apparatus which comprises a main frame, a power module, and a fan module. The main frame has a first side surface and a second side surface adjacent to each other. An external alarming output/input interface, a display light set, and a plurality of serial COM ports are disposed on the first side surface. Furthermore, the first side surface has a first opening and a second opening, wherein the second opening is adjacent to the joint between the first side surface and the second side surface. The second side surface has a third opening. The power module, removable from the main frame, is installed in and electrically connected to the main frame through the first opening. The fan module, removable from the main frame, is installed in and electrically connected to the main frame through the second opening, wherein the airflow direction of the fan module is toward the third opening.

According to the network apparatus in an embodiment of the present invention, at least one expansion module is further comprised and the first side surface is further provided with a fourth opening, wherein the expansion module, removable from the main frame, is installed in and electrically connected to the main frame through the fourth opening.

According to the network apparatus in an embodiment of the present invention, the expansion module is one of a dual GPON module, single GPON/GEPON module, dual GigE COMBO module, single GigE COMBO module, network processor module, and TDM module.

According to the network apparatus in an embodiment of the present invention, the power module supplies an AC power or a DC power.

According to the network apparatus in an embodiment of the present invention, the power module comprises a plurality of secondary power modules.

According to the network apparatus in an embodiment of the present invention, the network apparatus is a switch which is one of an Ethernet switch, fiber-to-the-home (FTTH) switch, very-high-bit-rate digital subscriber line 2 (VDSL2) switch, or the other kinds of switches.

According to the network apparatus in an embodiment of the present invention, the serial COM ports are at least one of RJ-45 connectors, SC fiber optic connectors, and RJ-21 connectors.

According to the network apparatus in an embodiment of the present invention, the network apparatus is a hub.

As the power module, fan module, external alarming output/input interface, display light set, and serial COM ports of the network apparatus are disposed at the same side of the network apparatus, the present invention can reduce the space required for constructing the network apparatus compared with the conventional art.

In order to the make the aforementioned and other objects, features and advantages of the present invention comprehensible, preferred embodiments accompanied with figures are described in detail below.

### BRIEF DESCRIPTION OF THE DRAWINGS

FIG. 1 is a schematic view of the network apparatus according to an embodiment of the present invention.

FIG. 2 is a schematic view of the network apparatus according to another embodiment of the present invention.

FIG. 3 is a schematic view of the network apparatus according to still another embodiment of the present invention.

FIG. 4 is a schematic view of the network apparatus according to yet another embodiment of the present invention.

FIG. 5 is a flowchart illustrating a method for manufacturing a network apparatus according to an embodiment of the present invention.

### DESCRIPTION OF EMBODIMENTS

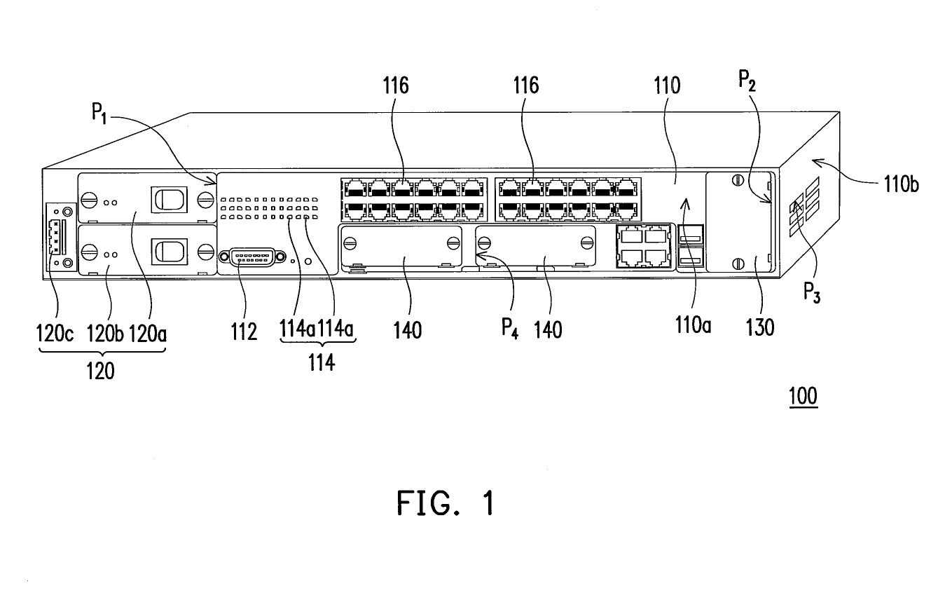

FIG. 1 is a schematic view of the network apparatus according to an embodiment of the present invention. Referring to FIG. 1, a network apparatus 100 mainly comprises a main frame 110, a power module 120, and a fan module 130. The main frame 110 has a first side surface 110a and a second side surface 110b adjacent to each other. An external alarming output/input interface 112, a display light set 114, and a plurality of serial COM ports 116 are disposed on the first side surface 110a, wherein the display light set 114 comprises a plurality of display lights 114a, and the serial COM ports 116 are RJ-45 connectors. The first side surface 110a has a first opening P₁ and a second opening P₂, wherein the second opening P₂ is adjacent to the joint between the first side surface 110a and the second side surface 110b. The second side surface 110b has a third opening P₃. In the present embodiment, the network apparatus 100 is, for example, a switch, and more particularly, an Ethernet switch.

The power module 120, removable from the main frame, is installed in and electrically connected to the main frame 110 through the first opening P₁. The power module 120 can comprise a plurality of secondary power modules. For example, in the present embodiment, the power module 120 comprises a secondary power module 120a, a secondary power module 120b, and a secondary power module 120c, wherein each of the secondary power modules 120a˜120c can output DC current or AC current. In other words, when the power module 120 comprises a plurality of secondary power modules (for example, 120a˜120c), according to the present embodiment, the power module 120 can output either AC current or DC current or output both AC current and DC current at the same time by appropriately selecting the types of the power source output by the secondary power modules (for example, 120a˜120c).

Preferably, the power modules 120a˜120c can further have a hot-plug function. As such, the user can remove and replace the power modules 120a˜120c when the network apparatus 100 is in operation. Further, the power module 120 in the present embodiment is not limited to have a plurality of secondary power modules, and in other embodiments of the present invention, the power module 120 can be a single power supply device for providing AC current or DC current only.

The fan module 130, removable from the main frame, is installed in and electrically connected to the main frame 110 through the second opening P₂. The fan module 130 blows to the third opening P₃. Since the second opening P₂ is adjacent to the joint between the first side surface 110a and the second side surface 110b, and the fan module 130 blows to the third opening P₃, when the main frame 110 is in operation, the fan module 130 can exhaust the heat (or hot air) in the main frame 110 through the third opening P₃.

Moreover, in order to extend the function of the main frame 110 or improve the performance of the main frame 110, the network apparatus 100 of the present embodiment can further comprise at least one expansion module 140 that is one of a dual GPON module, a single GPON/GEPON module, a dual GigE COMBO module, a single GigE COMBO module, a network processor module, and a TDM module. When the network apparatus 100 comprises an expansion module 140, the first side surface 110a is provided with a corresponding fourth opening P₄. As such, the expansion module 140, removable from the main frame, is installed in and electrically connected to the main frame 110 through the fourth opening P₄.

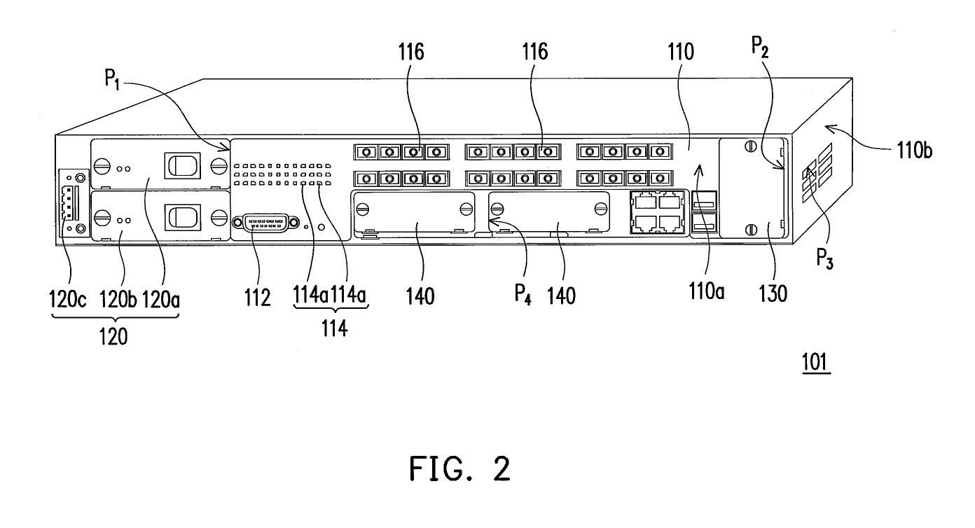

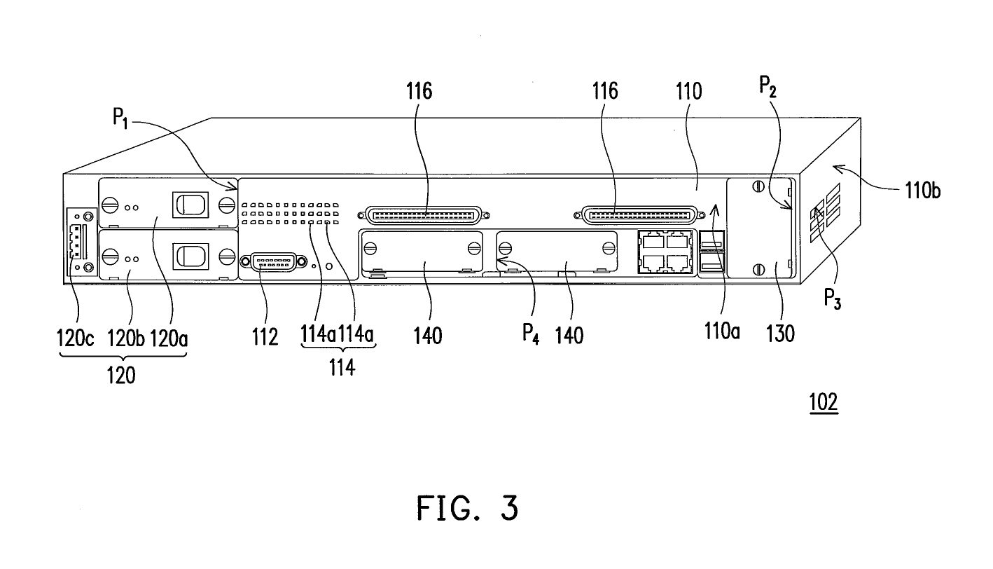

Furthermore, although the network apparatus 100 of FIG. 1 of the present invention is an Ethernet switch, but it is not limited to this. For example, when the serial COM ports 116 are SC fiber optic connectors, the network apparatus 101 is an FTTH switch, as shown in FIG. 2. When the serial COM ports 116 are RJ-21 connectors, the network apparatus 102 is a VDSL2 switch, as shown in FIG. 3. Of course, in other embodiments of the present invention, the serial COM ports 116 can comprise two or more types of connectors at the same time. For example, the serial COM ports 116 comprise SC fiber optic connectors and RJ-21 connectors.

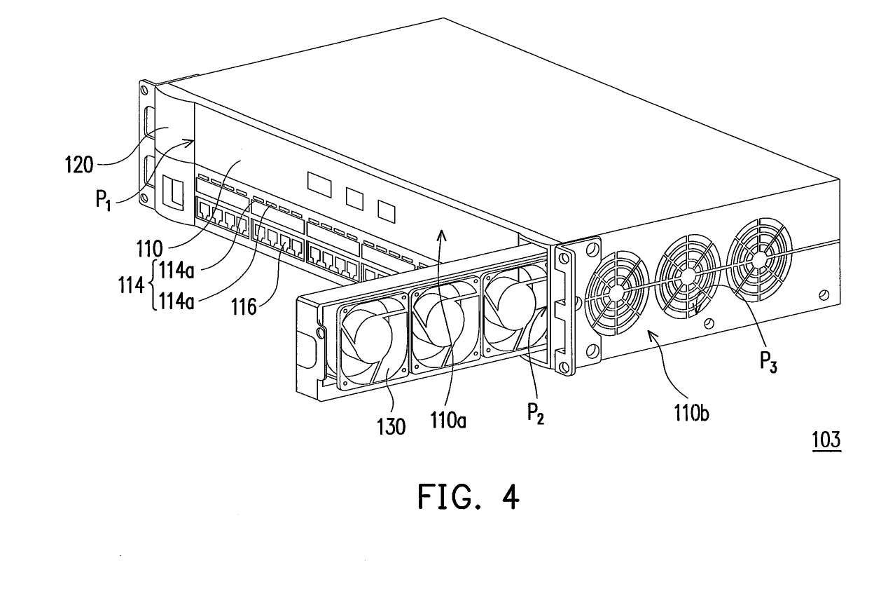

It should be noted that the relative position of the external alarming output/input interface 112, display light set 114, serial COM ports 116, power module 120, and fan module 130 of the present invention is not limited to that of FIG. 1. For example, FIG. 4 is a schematic view of the network apparatus according to another embodiment of the present invention. The main difference between a network apparatus 103 and the network apparatus 100 lies in that the relative positions of the display light set 114, serial COM ports 116, power module 120, and fan module 130 are different. In other words, one of the main spirits of the present invention is that the external alarming output/input interface 112, display light set 114, serial COM ports 116, power module 120, and fan module 130 are disposed at the same side surface of the network apparatus 100. Those of ordinary skill in the art can adjust the relative position of the external alarming output/input interface 112, display light set 114, serial COM ports 116, power module 120, and fan module 130 in practice without departing from the spirit of the present invention. Of course, those of ordinary skill in the art can change the profile of the third opening P₃ in FIG. 1 into that of the third opening P₃ in FIG. 4 or another profile, and the details will not be described herein.

Moreover, in FIG. 4, the fan module 130 is in a drawn-out state. It should be noted that the number of the fans of the fan module 130 is not limited to that of the present embodiment, and in other embodiments of the present invention, the fan module 130 can comprise a single fan or two or more fans.

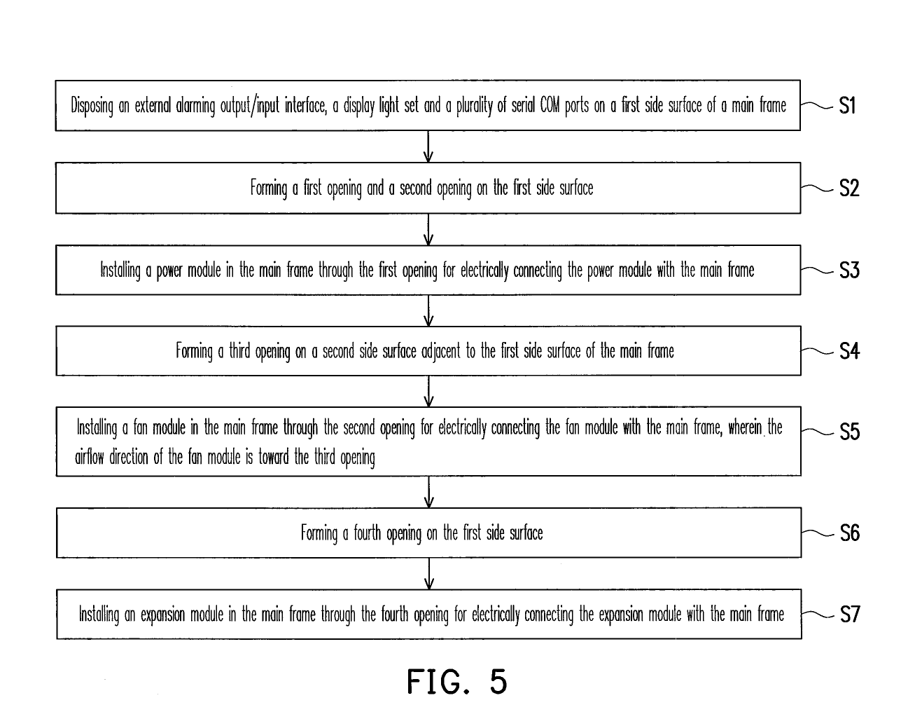

FIG. 5 is a flowchart illustrating a method for manufacturing a network apparatus according to an embodiment of the present invention. Referring to FIG. 5, a method for manufacturing a network apparatus is illustrated as followed steps. In the step S1, an external alarming output/input interface, a display light set and a plurality of serial COM ports are disposed on a first side surface of a main frame. In the step S2, a first opening and a second opening are formed on the first side surface. In the step S3, a power module is installed in the main frame through the first opening for electrically connecting the power module with the main frame. In the step S4, a third opening is formed on a second side surface adjacent to the first side surface of the main frame. In the S5, a fan module is installed in the main frame through the second opening for electrically connecting the fan module with the main frame, wherein the airflow direction of the fan module is toward the third opening. In the step S6, a fourth opening is formed on the first side surface. In the step S7, a expansion module is installed in the main frame through the fourth opening for electrically connecting the expansion module with the main frame.

In view of the above, as the external alarming output/input interface, display light set, serial COM ports, power module, and fan module of the present invention are disposed at the same side surface of the network apparatus, when constructing the network apparatus, the user only needs to reserve a sufficient space in the front of the network apparatus for accommodating the power lines and wirings connected to the power module, external alarming output/input interface, and serial COM ports. Thus, compared with the conventional art, the present invention does not require an extra space at the back of the network apparatus for accommodating the electrical wires connected to the power module, so the present invention can reduce the space required for constructing the network apparatus.

Further, as the external alarming output/input interface, display light set, serial COM ports, power module, and fan module of the present invention are disposed at the same side surface of the network apparatus, and the power module and fan module are removably installed in the main frame, the present invention is more convenient in repairing than the conventional art.

Though the present invention has been disclosed above by the preferred embodiments, they are not intended to limit the invention. Anybody skilled in the art can make some modifications and variations without departing from the spirit and scope of the present invention. Therefore, the protecting range of the present invention falls in the appended claims.

What is claimed is:

1. A network apparatus, comprising:
a main frame having a first side surface and a second side surface adjacent to each other, wherein an external alarming output/input interface, a display light set and a plurality of serial COM ports are disposed on the first side surface; the first side surface has a first opening and a second opening, in which the second opening is adjacent to the joint between the first side surface and the second side surface; and the second side surface has a third opening;
a power module, removable from the main frame, being installed in and connected to the main frame through the first opening; and
a fan module, removable from the main frame, being installed in and connected to the main frame through the second opening, wherein the airflow direction of the fan module is toward the third opening.

2. The network apparatus according to claim 1, further comprising at least one expansion module, wherein the first side surface has a fourth opening, and the expansion module, removable from the main frame, is installed in and connected to the main frame through the fourth opening.

3. The network apparatus according to claim 2, wherein the expansion module is a dual GPON module, single GPON/GEPON module, dual GigE COMBO module, single GigE COMBO module, network processor module, or TDM module.

4. The network apparatus according to claim 1, wherein the power module supplies an AC power or a DC power.

5. The network apparatus according to claim 1, wherein the power module comprises a plurality of secondary power modules.

6. The network apparatus according to claim 1, wherein the network apparatus is a switch.

7. The network apparatus according to claim 6, wherein the switch is an Ethernet switch.

8. The network apparatus according to claim 6, wherein the switch is a fiber-to-the-home (FTTH) switch.

9. The network apparatus according to claim 6, wherein the switch is a very-high-bit-rate digital subscriber line 2 (VDSL2) switch.

10. The network apparatus according to claim 1, wherein the serial COM ports are at least one of RJ-45 connectors, SC fiber optic connectors, and RJ-21 connectors.

11. The network apparatus according to claim 1, wherein the network apparatus is a hub.

12. A method for manufacturing a network apparatus, comprising:
disposing an external alarming output/input interface, a display light set and a plurality of serial COM ports on a first side surface of a main frame;
forming a first opening and a second opening on the first side surface;
installing a power module in the main frame through the first opening for electrically connecting the power module with the main frame;
forming a third opening on a second side surface adjacent to the first side surface of the main frame; and
installing a fan module in the main frame through the second opening for electrically connecting the fan module with the main frame, wherein the airflow direction of the fan module is toward the third opening.

13. The method for manufacturing a network apparatus according to claim 12, further comprising:
forming a fourth opening on the first side surface; and
installing a expansion module in the main frame through the fourth opening for electrically connecting the expansion module with the main frame.
